(19) United States
(12) Patent Application Publication
(10) Pub. No.: US 2023/0238068 A1
(43) Pub. Date: Jul. 27, 2023

(54) DATA STORAGE CONTROL METHOD, ELECTRONIC DEVICE, AND STORAGE MEDIUM

(71) Applicant: Zhuhai Pantum Electronics Co., Ltd., Zhuhai (CN)

(72) Inventor: Xiaohu WU, Zhuhai (CN)

(21) Appl. No.: 18/100,442

(22) Filed: Jan. 23, 2023

(30) Foreign Application Priority Data
Jan. 24, 2022 (CN) 202210079888.7

(51) Int. Cl. G11C 16/34

(52) U.S. Cl. CPC G11C 16/3495

(57) ABSTRACT

The present disclosure provides a data storage control method, an electronic device, and a storage medium. The data storage control method includes obtaining lifespans of a plurality of memory blocks in a flash memory and selecting at least one target memory block according to the lifespans of the plurality of memory blocks, where the at least one target memory block is configured to store data to-be-written; determining a limit storage block with a shortest lifespan in the at least one target memory block; and outputting first prompt information according to the limit storage block and/or a lifespan of at least one memory block, where the first prompt information is configured to prompt lifespan information of the flash memory.

### CROSS-REFERENCE TO RELATED APPLICATION

This application claims the priority to Chinese patent application No. 202210079888.7, filed on Jan. 24, 2022, in the China National Intellectual Property Administration, the entirety of which is incorporated herein by its reference.

### TECHNICAL FIELD

The present disclosure generally relates to the field of data storage technology and, more particularly, relates to a data storage control method, an electronic device, and a storage medium.

### BACKGROUND

NAND flash memory, which has the advantages of large capacity, fast rewriting speed and the like, is suitable for storing a large amount of data. Therefore, NAND flash memory is normally configured to store certain crucial data. However, the quantity of the erase/writing cycles of the NAND flash memory is limited. When the quantity of the erase/writing cycles reaches limit, data may no longer be written, which indicates that the lifespan of the NAND flash is exhausted at this point. Since the lifespan of the NAND flash cannot be observed in real time during system operation, when the system or the firmware is updated, it is not possible to choose whether such upgrade is performed according to the lifespan of the NAND flash. Therefore, when the system or the firmware is updated, it may cause system startup failure if the NAND flash memory is exhausted.

### SUMMARY

One aspect of the present disclosure provides a data storage control method. The method includes obtaining lifespans of a plurality of memory blocks in a flash memory and selecting at least one target memory block according to the lifespans of the plurality of memory blocks, where the at least one target memory block is configured to store data to-be-written; determining a limit storage block with a shortest lifespan in the at least one target memory block; and outputting first prompt information according to the limit storage block and/or a lifespan of at least one memory block, where the first prompt information is configured to prompt lifespan information of the flash memory.

Another aspect of the present disclosure provides an electronic device. The electronic device includes a selecting unit, configured to obtain lifespans of a plurality of memory blocks in a flash memory and select at least one target memory block according to the lifespans of the plurality of memory blocks, where the at least one target memory block is configured to store data to-be-written; a determining unit, configured to determine a limit storage block with a shortest lifespan in the at least one target memory block; and an output unit, configured to output first prompt information according to the limit storage block and/or a lifespan of at least one memory block, where the first prompt information is configured to prompt lifespan information of the flash memory.

Another aspect of the present disclosure provides a non-transitory computer-readable storage medium containing a computer program, where when being executed, the computer program causes a processor to perform a data storage control method. The method includes obtaining lifespans of a plurality of memory blocks in a flash memory and selecting at least one target memory block according to the lifespans of the plurality of memory blocks, where the at least one target memory block is configured to store data to-be-written; determining a limit storage block with a shortest lifespan in the at least one target memory block; and outputting first prompt information according to the limit storage block and/or a lifespan of at least one memory block, where the first prompt information is configured to prompt lifespan information of the flash memory.

Other aspects of the present disclosure may be understood by those skilled in the art in light of the description, the claims, and the drawings of the present disclosure.

### BRIEF DESCRIPTION OF THE DRAWINGS

To clearly describe technical solutions of various embodiments of the present disclosure, the drawings, which need to be used for describing various embodiments, are described below. Obviously, the drawings in the following description are merely some embodiments of the present disclosure. For those skilled in the art, other drawings may be obtained in accordance with these drawings without creative efforts.

FIG. 1 illustrates a flowchart of a data storage control method according to exemplary embodiments of the present disclosure.

FIG. 2 illustrates a schematic of an application scenario of an electronic device according to exemplary embodiments of the present disclosure.

FIG. 3 illustrates a structural schematic of an electronic device according to exemplary embodiments of the present disclosure.

### DETAILED DESCRIPTION

To better understand technical solutions of the present disclosure, embodiments of the present disclosure are described in detail with reference to accompanying drawings.

It should be noted that described embodiments are only a part of embodiments of the present disclosure, rather than all embodiments. Based on embodiments in the present disclosure, all other embodiments obtained by those skilled in the art without creative work shall fall within the protection scope of the present disclosure.

The terms used in embodiments of the present disclosure are only for the purpose of describing specific embodiments and are not intended to limit the present disclosure. The singular forms of “a”, “the” and “said” used in embodiments of the present disclosure and the appended claims are also intended to include plural forms, unless the context clearly indicates other meanings.

It may be understood that the term “and/or” used in the specification may only be an association relationship describing associated objects, which indicates that there may be three types of relationships. For example, A and/or B can mean that: A alone exists, A and B exist at the same time, and B exists alone. In addition, the character “/” in the specification normally indicates that associated objects before and after are in an “or” relationship.

In order to facilitate those skilled in the art to better understand the technical solutions of the present disclosure, the terms in embodiments of the present disclosure are first explained below.

Image-forming apparatuses may include, but may not be limited to, printers, copiers, fax machines, scanners, and all-in-one machines that integrate functions such as printing, copying, faxing, and scanning, and the like; and the function of the image-forming apparatuses is to print images or text on image-forming media.

NAND flash memory is also known as non-linear flash memory, and non-flash memory. NAND flash memory is one type of flash memory, and its internal nonlinear macro-cell mode provides a cheap and effective solution for realization of solid-state large-capacity memory. NAND flash memory has the advantages of large capacity and fast rewriting speed and is suitable for storing a large amount of data. NAND flash memory is one type of non-transitory storage, the physical storage structure is in blocks, and each block is divided into a plurality of pages. There is additional out of band data (OOB data) in each page, which is configured to verify the data content of current page and mark bad blocks. After the NAND flash memory is shipped from the factory, some bad blocks may appear in random locations. Bad blocks, simply put, are some address segments of NAND flash memory which cannot be read or written. The bad blocks use blocks as the unit; and as long as there is a page on the block that cannot be read or written, then entire block is marked as a bad block.

Bad blocks indicate that some flash areas in NAND flash memory cannot be erased and written, and such a unit area is one bad block. The reading and writing operations in the NAND flash memory are based on page units, erasing operation is based on block units, and the erasing operation must be performed before the writing operation. Therefore, a smallest operable unit is a block. Any unrecoverable bit error in entire block makes such block a bad block. Bad blocks of NAND flash memory may affect normal use of the terminal equipment, such as the equipment cannot be turned on after software (version) is burned to the NAND flash memory, or the version is used abnormally after software (version) is burned. Above situation may bring significant losses to manufacturers and users.

BBT (bad block table) is described as the following. In order to ensure the reliability of NAND flash memory, it is required to add a bad block table in the software solution when designing the software of NAND flash memory device and use the bad block table to identify all bad blocks; and when a block is found to be a bad block, the replacement block is configured to replace the bad block.

NAND flash memory, which has the advantages of large capacity, fast rewriting speed and the like, is suitable for storing a large amount of data. Therefore, NAND flash memory is normally configured to store certain crucial data. However, the quantity of the erase/writing cycles of the NAND flash memory is limited. When the quantity of the erase/writing cycles reaches limit, data may no longer be written, which indicates that the lifespan of the NAND flash is exhausted at this point. Since the lifespan of the NAND flash cannot be observed in real time during system operation, when the system or the firmware is updated, it is not possible to choose whether such upgrade is performed according to the lifespan of the NAND flash. Therefore, when the system or the firmware is updated, it may cause system startup failure if the NAND flash memory is exhausted.

Based above, embodiments of the present disclosure provide a data storage control method to solve the problem in the existing technology that the user cannot know the lifespan of the flash memory which results in the failure of data writing, thereby avoiding affecting normal use of electronic devices.

Referring to FIG. 1, FIG. 1 illustrates a flowchart of a data storage control method according to exemplary embodiments of the present disclosure. As shown in FIG. 1, the method may at least include following exemplary steps.

At S10, the lifespans of a plurality of memory blocks in the flash memory may be obtained, and at least one target memory block may be selected according to the lifespans of the plurality of memory blocks, where the at least one target memory block may be configured to store data to-be-written.

Before S10, the method may further include calculating the memory block capacity occupied by the data to-be-written.

At S20, the limit storage block with the shortest lifespan in at least one target memory block may be determined.

At S30, the first prompt information may be outputted according to the limit storage block and/or the lifespan of at least one memory block, where the first prompt information may be configured to prompt the lifespan information of the flash memory.

In such solution, required target memory block may be determined according to the lifespan of each memory block in the flash memory, and the memory block with more remaining lifespan may be configured to store data, which may ensure that the data may be written normally, and may avoid that the data cannot be written when writing data because the remaining lifespan of the memory block is significantly low.

The lifespan information of the block with the lowest remaining lifespan in the target memory block may be outputted. When the blocks with higher lifespans in the target memory block are not sufficient to support data writing, it may indicate that the flash memory is about to be damaged, and whether the flash memory is about to be damaged may be determined without knowing the lifespans of other storage blocks, which may simplify determination process. In addition, the lifespan information may be prompted so that the user may perform data backup and other related processing in advance, which may prevent important data loss and ensure normal use of electronic devices.

Through such solution, the remaining lifespan of the flash memory may be observed at any time during the system operation, and the user may back up the data in advance when the flash memory is about to be damaged, which may prevent important data loss. When performing system or firmware update, whether such upgrade is performed may be chosen according to the remaining lifespan of the flash memory, which may avoid that exhausted lifespan of the flash memory results in the system startup failure when the system or firmware is updated.

A controller may be configured in the flash memory, and above-mentioned method may be controlled and implemented by the controller. The following describes such solution with specific implementation examples.

Referring back to S10, the lifespans of the plurality of memory blocks in the flash memory may be obtained, and at least one target memory block may be selected according to the lifespans of the plurality of memory blocks, where the target memory block may be configured to store data to-be-written.

Before S10, the method may further include calculating the memory block capacity occupied by the data to-be-written.

The quantity of memory blocks occupied by the data to-be-written may be calculated according to the file size of the data to-be-written. In practical applications, the flash memory may be NAND flash memory. NAND flash memory is normally used as a system disk, which saves important information such as system boot image and system configuration.

Exemplarily, the file size of the data to-be-written is 250k, and the capacity size of each memory block in the memory is 128k, such that the quantity of memory blocks occupied by the data to-be-written is n*128-250>0, and n is calculated to be n=2. Therefore, 2 memory blocks are required to store the data to-be-written.

For example, S10 may include reading the quantity of erasing programming of each memory block recorded in the erasing programming table pre-stored in the flash memory; and calculating the lifespan of each memory block according to the erasing programming times of each memory block.

In practical application processes, the quantity of times that NAND flash memory may be read and written is limited, and the theoretical value of the quantity of erasing programming of each memory block is x (for example, 100,000 times). The cumulative erasing programming times of the memory block represents the space occupied by erasing and writing of the memory block but does not represent the lifespan of the memory block. The lifespan of the memory block refers to the remaining quantity of reading and writing in the memory block. If the limit of the remaining quantity of reading and writing is reached, data cannot be written any more. For example, if the quantity of reading and writing reaches 100,000, theoretically, data cannot be written.

Therefore, before writing data, it is required to estimate in advance whether the lifespan of the memory block occupied by data writing is allowed for writing data. Each page of NAND flash memory may be divided into data partition and free partition. The quantity of erasing programming may be written into the free partition of a specific page in each memory block, and the lifespan of each memory block in each partition may be recorded.

In some embodiments, the NAND flash memory may include a plurality of partitions, the partitions may be configured by the user according to actual needs, and each partition may have multiple memory blocks. The NAND flash memory may create an erasing programming table based on the quantity of NAND flash erasing operations recorded in the free partition of a specific page of the memory block, record the quantity of times that each memory block is erased and programmed, and save the table in the preset partition of the NAND flash memory. When the memory block has an erasing programming operation, the erasing programming times of the block recorded in the free partition of the specific page of the memory block and the erasing programming table in the preset partition may be updated simultaneously.

Every time the memory block has an operation (programming or erasing), the quantity of times that each block has been erased and programmed in the partition recorded in the erasing programming table may be first read, and the lifespan of each NAND may be finally calculated and obtained according to the theoretical value of the quantity of erasing programming of the NAND flash memory.

Exemplarily, the theoretical value of the quantity of erasing programming operations of each memory block in the NAND flash memory is x (e.g., 100,000 times), and actual quantity of erasing programming operations of each memory block is y, then the lifespan of the memory block may be calculated as (1−(y/x))×100%.

For the bad block marked in the NAND flash memory, the lifespan may be recorded as 0. The remaining lifespan of each memory block in partition 1 of the NAND flash memory is shown in Table 1 below.

TABLE 1

| Memory | Memory | Memory | . . . | Memory | Memory | Memory |
|---|---|---|---|---|---|---|
| block 1 | block 2 | block 3 | | block n | block n + 1 | block n + 2 |
| lifespan | lifespan | lifespan | | lifespan | lifespan | lifespan |
| 50% | 50% | 0% | | 75% | 60% | 75% |

If the remaining lifespan of the memory block is not sufficient to store the writing of the data to-be-written, forcibly writing the data to-be-written may cause damage to the memory, complete writing failure or the like, thereby affecting normal operation of electronic devices.

Therefore, it is required to calculate the quantity of memory blocks occupied by the data according to the size of the data to-be-written and obtain the remaining lifespan of each memory block in the flash memory.

In some embodiments, selecting at least one target memory block according to the lifespans of the plurality of memory blocks may include that the plurality of memory blocks may be sorted by size according to the lifespans of the plurality of memory blocks; and at least one target memory block may be sequentially selected from the plurality of memory blocks sorted.

It should be understood that, using the memory block with long remaining lifespan to store data may ensure that the data may be written normally, which may avoid that the data cannot be written due to the low lifespan of the memory block when writing data.

Exemplarily, after sorting each memory block in partition 1 of the memory according to the lifespans, for example, after sorting the lifespans from long to short, the result is shown in Table 2.

TABLE 2

| Memory | Memory | Memory | . . . | Memory | Memory | Memory |
|---|---|---|---|---|---|---|
| block n | block n + 2 | block n + 1 | | block 1 | block 2 | block 3 |
| lifespan | lifespan | lifespan | | lifespan | lifespan | lifespan |
| 75% | 75% | 60% | | 50% | 50% | 0% |

Furthermore, it is required to determine whether the remaining lifespan of the first two memory blocks in the partition to be operated allows the operation. For example, the lifespan of memory block n is 25,000 times, and 75% of the lifespan is remained; and the lifespan of memory block n+2 is 25,000 times, and 75% of the lifespan is remained, data writing may continue. Therefore, two memory blocks, including the memory block n and the memory block n+2, may be selected as target memory blocks for storing the data to-be-written.

Referring back to S20, the limit storage block with the shortest lifespan in at least one target memory block may be determined.

In order to further ensure data writing, the limit storage block with the shortest lifespan in at least one target memory block may be determined. Exemplarily, the remaining lifespans of the memory block n and the memory block n+2 are both 75%, so that the lifespan of the limit storage block may be 75%.

Referring back to S30, the first prompt information may be outputted according to the limit storage block and/or the lifespan of at least one memory block, where the first prompt information may be configured to prompt the lifespan information of the flash memory.

The memory block with the shortest lifespan among the target memory blocks occupied by the data to-be-written at this time may be configured as the limit storage block, and the first prompt information may be outputted according to the lifespan of the limit storage block and/or at least one memory block. It should be understood that the lifespan information of the block with the lowest remaining lifespan in the target memory block may be outputted. When the blocks with higher lifespans in the target memory block are not sufficient to support data writing, it may indicate that the flash memory is about to be damaged, and whether the flash memory is about to be damaged may be determined without knowing the lifespans of other storage blocks, which may simplify determination process. In addition, the lifespan information may be prompted so that the user may perform data backup and other related processing in advance, which may prevent important data loss and ensure normal use of electronic devices. For example, the first prompt message may be sentences such as “the remaining lifespan of the flash memory is 10%, please contact a technician for replacement”.

If the remaining lifespan of the memory block reaches 10%, it indicates that the lifespan of the memory block is about to reach the limit, and the first prompt information including the lifespan of the limit storage block may need to be outputted for reminding the user.

In other embodiments, the lifespan information of the flash memory may also be the lifespan of at least one memory block, that is, when the first prompt information is outputted, the first prompt information may include the lifespans of the plurality of memory blocks, which may not be limited herein.

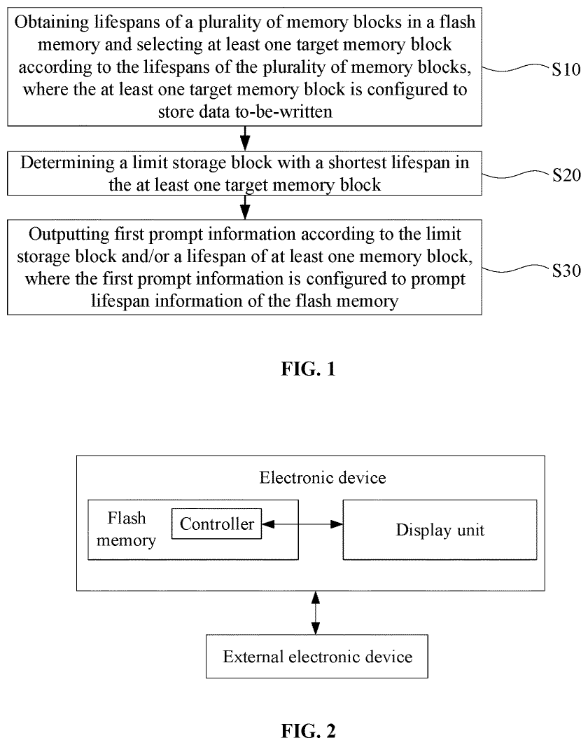

In some embodiments, as shown in FIG. 2, when the controller in the flash memory is communicatively connected with the display unit of the electronic device, the first prompt information may be outputted to the display unit and/or the webpage of the electronic device. For example, the form of the first prompt information may include at least one of texts, files, pictures, folders, short messages, and emails. Exemplarily, the first prompt information may be exported in a format such as a JPEG file, a BMP file, a PNG file, a TIFF file, an OFD file, or a PDF file, and displayed on the display of the electronic device.

In some other embodiments, when the controller in the flash memory is communicatively connected to the external electronic device, the first prompt information may also be sent to external electronic devices. External electronic devices may be, for example, information devices, mobile terminals, computer terminals, image-forming equipment, servers, U disks, file transfer protocol servers and the like. At this point, the first prompt information may be a picture, a file, a folder, an email or the like, which may not be limited herein.

The (web) page may be a webpage, a page opened by a browser, or the like.

In practical application processes, the first prompt information may be actively outputted by the electronic device, or passively outputted after the external electronic device sends an output request.

After the lifespan information of the flash memory is exported to the electronic device, the lifespan information may be sent to the lifespan administrator timedly or periodically through the external electronic device. For example, when the electronic device is an image-forming apparatus and the lifespan information of the flash memory in the image-forming apparatus is exported to the external electronic device (for example, computer terminal), the computer terminal may timedly or periodically send the lifespan information to the mobile terminal of the lifespan administrator. Therefore, the lifespan administrator may obtain the lifespan information of the flash memory in time, which is convenient for the lifespan administrator to effectively maintain the flash memory, thereby ensuring normal use of the electronic device.

Obviously, the lifespan information of the flash memory may also be sent to an information management device (for example, flash memory management computer) corresponding to the lifespan information timedly or periodically.

When the external electronic device is a mobile terminal, the user may view the lifespan information of the flash memory through a web application unit interface on the mobile terminal.

In some other embodiments, the image-forming apparatus may be configured to print out the first prompt information. For example, text or pictures may be directly transmitted to the image-forming apparatus to be printed out, such that the user may obtain the prompt information.

Furthermore, after S30, the method may further include writing the data to-be-written into the target memory block based on the writing instruction inputted by the user; and updating the erasing programming table pre-stored in the flash memory.

It should be understood that whether writing the data to-be-written into the flash memory (NAND flash memory) and updating the erasing programming table is performed may be determined based on detected user writing instruction.

After receiving the writing instruction inputted by the user, when writing data (such as system upgrade or firmware update) is performed, whether writing data is performed may be selected based on the user's operation selection, which may prevent data writing failure and system startup failure due to that the lifespan of the NAND flash memory is exhausted.

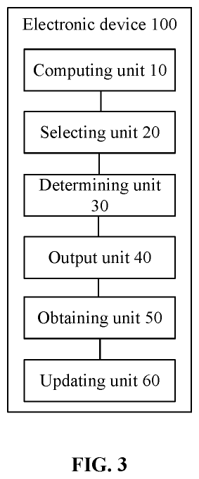

In the second aspect, embodiments of the present disclosure provide an electronic device. As shown in FIG. 3, an electronic device 100 may include a selecting unit 20 which is configured to obtain the lifespans of the plurality of memory blocks in the flash memory and select at least one target memory block according to the lifespans of the plurality of memory blocks, where the at least one target memory block is configured to store data to-be-written; a determining unit 30, which is configured to determine the limit storage block with the shortest lifespan in the at least one target memory block; and an output unit 40, which is configured to output the first prompt information according to the limit storage block and/or the lifespan of at least one memory block, where the first prompt information is configured to prompt the lifespan information of the flash memory.

In such solution, required target memory block may be determined according to the lifespan of each memory block in the flash memory, and the memory block with more remaining lifespan may be configured to store data, which may ensure that the data may be written normally, and may avoid that the data cannot be written when writing data because the remaining lifespan of the memory block is significantly low.

The lifespan information of the block with the lowest remaining lifespan in the target memory block may be outputted. When the blocks with higher lifespans in the target memory block are not sufficient to support data writing, it may indicate that the flash memory is about to be damaged, and whether the flash memory is about to be damaged may be determined without knowing the lifespans of other storage blocks, which may simplify determination process. In addition, the lifespan information may be prompted so that the user may perform data backup and other related processing in advance, which may prevent important data loss and ensure normal use of electronic devices.

Through such solution, the remaining lifespan of the flash memory may be observed at any time during the system operation, and the user may back up the data in advance when the flash memory is about to be damaged, which may prevent important data loss. When performing system or firmware update, whether such upgrade is performed may be chosen according to the remaining lifespan of the flash memory, which may avoid that exhausted lifespan of the flash memory results in the system startup failure when the system or firmware is updated.

The electronic device may include at least one of electronic devices including an image-forming apparatus and a mobile terminal. The mobile terminal may be a mobile phone, a notebook, a wearable electronic device or the like, which may not be limited herein.

For example, the electronic device may further include a computing unit 10, which may be configured to calculate the memory block capacity occupied by the data to-be-written. The calculating unit may calculate the quantity of memory blocks occupied by the data to-be-written according to the file size of the data to-be-written.

In practical applications, the flash memory may be NAND flash memory. NAND flash memory is normally used as a system disk, which saves important information such as system boot image and system configuration.

Exemplarily, the file size of the data to-be-written is 250k, and the capacity size of each memory block in the memory is 128k, such that the quantity of memory blocks occupied by the data to-be-written is n*128-250>0, and n is calculated to be n=2. Therefore, 2 memory blocks are required to store the data to-be-written.

Furthermore, the selecting unit 20 may include an obtaining sub-unit.

The obtaining sub-unit may be configured to read the quantity of erasing programming of each memory block recorded in the erasing programming table pre-stored in the flash memory; and calculate the lifespan of each memory block according to the erasing programming times of each memory block.

In practical application processes, the quantity of times that NAND flash memory may be read and written is limited, and the theoretical value of the quantity of erasing programming of each memory block is x (for example, 100,000 times). The cumulative erasing programming times of the memory block represents the space occupied by erasing and writing of the memory block but does not represent the lifespan of the memory block. The lifespan of the memory block refers to the remaining quantity of reading and writing in the memory block. If the limit of the remaining quantity of reading and writing is reached, data cannot be written any more. For example, if the quantity of reading and writing reaches 100,000, theoretically, data cannot be written.

Therefore, before writing data, it is required to estimate in advance whether the lifespan of the memory block occupied by data writing is allowed for writing data. Each page of NAND flash memory may be divided into data partition and free partition. The quantity of erasing programming may be written into the free partition of a specific page in each memory block, and the lifespan of each memory block in each partition may be recorded.

In some embodiments, the NAND flash memory may include a plurality of partitions, the partitions may be configured by the user according to actual needs, and each partition may have multiple memory blocks. The NAND flash memory may create an erasing programming table based on the quantity of NAND flash erasing operations recorded in the free partition of a specific page of the memory block, record the quantity of times that each memory block is erased and programmed, and save the table in the preset partition of the NAND flash memory. When the memory block has an erasing programming operation, the erasing programming times of the block recorded in the free partition of the specific page of the memory block and the erasing programming table in the preset partition may be updated simultaneously.

Every time the memory block has an operation (programming or erasing), the quantity of times that each block has been erased and programmed in the partition recorded in the erasing programming table may be first read, and the lifespan of each NAND may be finally calculated and obtained according to the theoretical value of the quantity of erasing programming of the NAND flash memory.

Exemplarily, the theoretical value of the quantity of erasing programming of each memory block in the NAND flash memory is x (e.g., 100,000 times), and the quantity of erasing programming of operating memory block is y, then the lifespan of the memory block may be calculated as (1−(y/x))×100%.

For the bad block marked in the NAND flash memory, the lifespan may be recorded as 0. The remaining lifespan of each memory block in partition 1 of the NAND flash memory is shown in Table 1 above.

If the remaining lifespan of the memory block is not sufficient to store the writing of the data to-be-written, forcibly writing the data to-be-written may cause damage to the memory, complete writing failure or the like, thereby affecting normal operation of electronic devices.

Therefore, it is required to calculate the quantity of memory blocks occupied by the data according to the size of the data to-be-written and obtain the remaining lifespan of each memory block in the flash memory.

Furthermore, the selecting unit 20 may include a selecting sub-unit.

The selecting sub-unit may be configured to sort the plurality of memory blocks by size according to the lifespans of the plurality of memory blocks; and sequentially select at least one target memory block from the plurality of memory blocks sorted.

It should be understood that, using the memory block with long remaining lifespan to store data may ensure that the data may be written normally, which may avoid that the data cannot be written due to the low lifespan of the memory block when writing data.

Exemplarily, each memory block in partition 1 of the memory may be sorted according to the lifespans from long to short.

Furthermore, it is required to determine whether the remaining lifespan of the first two memory blocks in the partition to be operated allows the operation. For example, the lifespan of memory block n is 25,000 times, and 75% of the lifespan is remained; and the lifespan of memory block n+2 is 25,000 times, and 75% of the lifespan is remained, data writing may continue. Therefore, two memory blocks, including the memory block n and the memory block n+2, may be selected as target memory blocks for storing the data to-be-written.

In order to further ensure data writing, the determining unit 30 may be configured to determine the limit storage block with the shortest lifespan in at least one target memory block. Exemplarily, the remaining lifespans of the memory block n and the memory block n+2 are both 75%, so that the lifespan of the limit storage block may be 75%.

The output unit 40 may be further configured to output the first prompt information according to the limit storage block and/or the lifespan of at least one memory block, where the first prompt information may be configured to prompt the lifespan information of the flash memory.

The memory block with the shortest lifespan among the target memory blocks occupied by the data to-be-written at this time may be configured as the limit storage block, and the first prompt information may be outputted according to the lifespan of the limit storage block and/or at least one memory block. It should be understood that the lifespan information of the block with the lowest remaining lifespan in the target memory block may be outputted. When the blocks with higher lifespans in the target memory block are not sufficient to support data writing, it may indicate that the flash memory is about to be damaged, and whether the flash memory is about to be damaged may be determined without knowing the lifespans of other storage blocks, which may simplify determination process. In addition, the lifespan information may be prompted so that the user may perform data backup and other related processing in advance, which may prevent important data loss and ensure normal use of electronic devices. For example, the first prompt message may be sentences such as “the remaining lifespan of the flash memory is 10%, please contact a technician for replacement”.

If the remaining lifespan of the memory block reaches 10%, it indicates that the lifespan of the memory block is about to reach the limit, and the first prompt information including the lifespan of the limit storage block may need to be outputted for reminding the user.

In other embodiments, the lifespan information of the flash memory may also be the lifespan of at least one memory block, that is, when the first prompt information is outputted, the first prompt information may include the lifespans of the plurality of memory blocks, which may not be limited herein.

In some embodiments, as shown in FIG. 2, when the controller in the flash memory is communicatively connected with the display unit of the electronic device, the first prompt information may be outputted to the display unit and/or the webpage of the electronic device. For example, the form of the first prompt information may include at least one of texts, files, pictures, folders, short messages, and emails. Exemplarily, the first prompt information may be exported in a format such as a JPEG file, a BMP file, a PNG file, a TIFF file, an OFD file, or a PDF file, and displayed on the display of the electronic device.

In some other embodiments, when the controller in the flash memory is communicatively connected to the external electronic device, the first prompt information may also be sent to external electronic devices. External electronic devices may be, for example, information devices, mobile terminals, computer terminals, image-forming equipment, servers, U disks, file transfer protocol servers and the like. At this point, the first prompt information may be a picture, a file, a folder, an email or the like, which may not be limited herein.

The (web) page may be a webpage, a page opened by a browser, or the like.

In practical application processes, the first prompt information may be actively outputted by the electronic device, or passively outputted after the external electronic device sends an output request.

After the electronic device obtains the lifespan information of the flash memory, the lifespan information may be sent to the lifespan administrator timedly or periodically through the external electronic device. For example, when the electronic device is an image-forming apparatus and the lifespan information of the flash memory in the image-forming apparatus is exported to the external electronic device (for example, computer terminal), the computer terminal may timedly or periodically send the lifespan information to the mobile terminal of the lifespan administrator. Therefore, the lifespan administrator may obtain the lifespan information of the flash memory in time, which is convenient for the lifespan administrator to effectively maintain the flash memory, thereby ensuring normal use of the electronic device.

Obviously, the lifespan information of the flash memory may also be sent to an information management device (for example, flash memory management computer) corresponding to the lifespan information timedly or periodically.

When the external electronic device is a mobile terminal, the user may view the lifespan information of the flash memory through a web application unit interface on the mobile terminal.

In some other embodiments, the output unit 40 may be configured to use the image-forming apparatus to print out the first prompt information. For example, text or pictures may be directly transmitted to the image-forming apparatus to be printed out, such that the user may obtain the prompt information.

Furthermore, the electronic device may further include an obtaining unit 50 and an updating unit 60.

The obtaining unit 50 may be configured for writing the data to-be-written into the target memory block based on the writing instruction inputted by the user.

The updating unit 60 may be configured for updating the erasing programming table pre-stored in the flash memory.

It should be understood that whether the data to-be-written is written into the flash memory (NAND flash memory) and the erasing programming table is updated may be determined based on detected user writing instruction.

After receiving the writing instruction inputted by the user, when writing data (such as system or firmware update) is performed, whether writing data is performed may be selected based on the user's operation, which may prevent data writing failure and system startup failure due to that the lifespan of the NAND flash memory is exhausted.

In the third aspect, the present disclosure further provides a non-transitory computer-readable storage medium, where the computer-readable non-transitory storage medium may store a program, and when the program is executed, the program may include a part or all of steps in various embodiments of the present disclosure. The storage medium may be a magnetic disk, an optical disc, a read-only memory (ROM) or a random access memory (RAM), and/or the like.

In an implementation, embodiments of the present disclosure further provide a computer program product, where the computer program product may include executable instructions, and when being executed on the computer, the executable instructions may make the computer to execute a part or all of steps in above-mentioned method embodiments.

From above-mentioned embodiments, it can be seen that the solutions according to the present disclosure may achieve at least following beneficial effects.

In embodiments of the present disclosure required target memory block may be determined according to the lifespan of each memory block in the flash memory, and the memory block with more remaining lifespan may be configured to store data, which may ensure that the data may be written normally and avoid that the data cannot be written when writing data because the remaining lifespan of the memory block is significantly low.

The lifespan information of the block with the lowest remaining lifespan in the target memory block may be outputted. When the blocks with higher lifespans in the target memory block are not sufficient to support data writing, it may indicate that the flash memory is about to be damaged, and whether the flash memory is about to be damaged may be determined without knowing the lifespans of other storage blocks, which may simplify determination process. In addition, the lifespan information may be prompted so that the user may perform data backup and other related processing in advance, which may prevent important data loss and ensure normal use of electronic devices.

In embodiments of the present disclosure, “at least one” refers to one or more, and “a plurality of” refers to two or more. “And/or” may describe the association relationship of the associated objects, indicating that there may be three types of relationships. For example, A and/or B may indicate the situations where A exists alone, A and B exist at the same time, and B exists alone, where A and B may be singular or plural. The character “/” may normally indicate that associated objects before and after may be in an “or” relationship. “Following at least one of” and similar expressions may refer to any combination of these items, including any combination of singular items or plural items. For example, at least one of a, b, and c may represent: a, b, c, a-b, a-c, b-c, or a-b-c, where a, b, and c may be singular or plural.

Those skilled in the art should understand that the units and steps described in embodiments in the present disclosure may be implemented by a combination of electronic hardware, computer software, and electronic hardware. Whether these functions are executed by hardware or software may depend on application and design constraint conditions of the technical solutions. Those skilled in the art may use different methods for each application to implement described functions, but such implementation should not be considered as beyond the scope of the present disclosure.

Those skilled in the art may clearly understand that, for the convenience and conciseness of the description, the working process of the system, apparatus and unit described above may refer to corresponding process in above-mentioned method embodiments, which may not be described in detail herein.

In certain embodiments provided by the present disclosure, if any function is implemented in the form of a software functional unit and sold or used as an independent product, the function may be stored in a computer-readable storage medium. Based on such understanding, the technical solution of the present disclosure, or the part that contributes to the existing technology, or the part of the technical solution may be embodied in the form of a software product in essence. The computer software product may be stored in a storage medium and include a plurality of instructions for causing a computer device (which may be a personal computer, a server, a network device or the like) to execute all or a part of the steps of the methods described in various embodiments of the present disclosure. The above-mentioned storage media may include various media that can store program code, including U disks, mobile hard disks, read-only memory (ROM), random access memory (RAM), magnetic disks, optical disks and/or the like.

The above may merely be embodiments of the present disclosure. Changes or substitutions which may be easily thought by those skilled in the art within the technical scope disclosed by the present disclosure should be covered by the protection scope of the present disclosure. The protection scope of the present disclosure shall be subject to the protection scope of the claims.

What is claimed is:

1. A data storage control method, comprising:
obtaining lifespans of a plurality of memory blocks in a flash memory and selecting at least one target memory block according to the lifespans of the plurality of memory blocks, wherein the at least one target memory block is configured to store data to-be-written;
determining a limit storage block with a shortest lifespan in the at least one target memory block; and
outputting first prompt information according to the limit storage block and/or a lifespan of at least one memory block, wherein the first prompt information is configured to prompt lifespan information of the flash memory.

2. The method according to claim 1, wherein outputting the first prompt information according to the limit storage block and/or the lifespan of the at least one memory block includes at least one of:
outputting the first prompt information to a display unit and/or a web page of an electronic device; or
printing to output the first prompt information by an image-forming apparatus.

3. The method according to claim 2, wherein:
a form of the first prompt information includes at least one of texts, files, pictures, folders, short messages, and emails.

4. The method according to claim 1, wherein selecting the at least one target memory block according to the lifespans of the plurality of memory blocks includes:
sorting the plurality of memory blocks by size according to the lifespans of the plurality of memory blocks; and
sequentially selecting the at least one target memory block from the sorted plurality of memory blocks.

5. The method according to claim 1, wherein obtaining the lifespans of the plurality of memory blocks in the flash memory includes:
reading a quantity of erasing programming operations of each memory block, which is recorded in an erasing programming table pre-stored in the flash memory; and
calculating a lifespan of each memory block according to the quantity of erasing programming operations of each memory block.

6. The method according to claim 1, after outputting the first prompt information according to the limit storage block and/or the lifespan of the at least one memory block, further including:
writing the data to-be-written into the at least one target memory block according to a writing instruction inputted by a user; and
updating the erasing programming table pre-stored in the flash memory.

7. The method according to claim 1, before obtaining the lifespans of the plurality of memory blocks in the flash memory and selecting the at least one target memory block according to the lifespans of the plurality of memory blocks, further including:
calculating a memory block capacity occupied by the data to-be-written.

8. The method according to claim 5, wherein:
the lifespan of each memory block=(1−(y/x))×100%, wherein x denotes a theoretical quantity of erasing programming operations of each memory block, and y denotes an actual quantity of erasing programming operations of each memory block.

9. The method according to claim 3, wherein:
the first prompt information is exported in a format including a JPEG file, a BMP file, a PNG file, a TIFF file, an OFD file, or a PDF file.

10. The method according to claim 2, wherein:
the first prompt information is actively outputted by the electronic device, or passively outputted after an external electronic device sends an output request.

11. The method according to claim 2, wherein:
after the lifespan information of the flash memory is exported to the electronic device, the lifespan information of the flash memory is sent to a lifespan administrator timedly or periodically through an external electronic device.

12. The method according to claim 2, wherein:
the lifespan information of the flash memory is also sent to an information management device corresponding to the lifespan information of the flash memory timedly or periodically.

13. An electronic device, comprising:
a selecting unit, configured to obtain lifespans of a plurality of memory blocks in a flash memory and select at least one target memory block according to the lifespans of the plurality of memory blocks, wherein the at least one target memory block is configured to store data to-be-written;
a determining unit, configured to determine a limit storage block with a shortest lifespan in the at least one target memory block; and
an output unit, configured to output first prompt information according to the limit storage block and/or a lifespan of at least one memory block, wherein the first prompt information is configured to prompt lifespan information of the flash memory.

14. The electronic device according to claim 13, wherein the output unit is further configured to:
output the first prompt information to a display unit and/or a web page of an electronic device; or
print to output the first prompt information by an image-forming apparatus.

15. The electronic device according to claim 14, wherein:
a form of the first prompt information includes at least one of texts, files, pictures, folders, short messages, and emails.

16. The electronic device according to claim 13, wherein:
the selecting unit includes a selecting sub-unit, wherein the selecting sub-unit is configured to:
sort the plurality of memory blocks by size according to the lifespans of the plurality of memory blocks; and
sequentially select the at least one target memory block from the sorted plurality of memory blocks.

17. The electronic device according to claim 13, wherein:
the selecting unit includes an obtaining sub-unit, wherein the obtaining sub-unit is configured to:
read a quantity of erasing programming operations of each memory block, which is recorded in an erasing programming table pre-stored in the flash memory; and
calculate a lifespan of each memory block according to the quantity of erasing programming operations of each memory block.

18. The electronic device according to claim 13, further including:
an obtaining unit, configured to write the data to-be-written into the at least one target memory block according to a writing instruction inputted by a user; and
an updating unit, configured to update the erasing programming table pre-stored in the flash memory.

19. The electronic device according to claim 13, wherein:
the electronic device includes at least one of an image-forming apparatus and a mobile terminal.

20. A non-transitory computer-readable storage medium containing a computer program, wherein when being executed, the computer program causes a processor to perform a data storage control method, the method comprising:
obtaining lifespans of a plurality of memory blocks in a flash memory and selecting at least one target memory block according to the lifespans of the plurality of memory blocks, wherein the at least one target memory block is configured to store data to-be-written;
determining a limit storage block with a shortest lifespan in the at least one target memory block; and
outputting first prompt information according to the limit storage block and/or a lifespan of at least one memory block, wherein the first prompt information is configured to prompt lifespan information of the flash memory.
